(19) United States
(12) Patent Application Publication
(10) Pub. No.: US 2012/0126239 A1
(43) Pub. Date: May 24, 2012

(54) LAYER STRUCTURES FOR CONTROLLING STRESS OF HETEROEPITAXIALLY GROWN III-NITRIDE LAYERS

(75) Inventors: Stacia Keller, Santa Barbara, CA (US); Nicholas Fichtenbaum, Santa Barbara, CA (US)

(73) Assignee: TRANSPHORM INC., Goleta, CA (US)

(21) Appl. No.: 12/953,769

(22) Filed: Nov. 24, 2010

(51) Int. Cl. H01L 29/20

(52) U.S. Cl. 257/76; 257/615; 257/E29.089

(57) ABSTRACT

A III-N layer structure is described that includes a III-N buffer layer on a foreign substrate, an additional III-N layer, a first III-N structure, and a second III-N layer structure. The first III-N structure atop the III-N buffer layer includes at least two III-N layers, each having an aluminum composition, and the III-N layer of the two III-N layers that is closer to the III-N buffer layer having the larger aluminum composition. The second III-N structure includes a III-N superlattice, the III-N superlattice including at least two III-N well layers interleaved with at least two III-N barrier layer. The first III-N structure and the second III-N structure are between the additional III-N layer and the foreign substrate.

### TECHNICAL FIELD

This invention relates to growth of III-Nitride semiconductor films on silicon substrates, and specifically to methods to manage stress in the films.

### BACKGROUND

As large native substrates for group III-Nitride (III-N) semiconductors are not yet widely available, III-N films, such as GaN and its alloys, are currently grown by heteroepitaxy on suitable non-III-N substrates. Typically, the films are grown on sapphire (Al₂O₃), silicon carbide (SiC), or silicon substrates. Silicon substrates are emerging as a particularly attractive substrate candidate for III-N layers due to their low cost, wide availability, large wafer sizes, thermal properties, and ease of integration with silicon-based electronics. However, due to the large lattice mismatch and thermal expansion coefficient mismatch between silicon and III-N materials, there is typically a net tensile stress in III-N epitaxial layers deposited directly on silicon substrates. This mismatch can result in cracking of the layers. Therefore thick III-N layers on silicon substrates that are crack-free and that exhibit adequate structural quality can be difficult to achieve. Structures that include additional layers between the III-N layer and the substrate for controlling stress during growth are therefore necessary to allow for growth of thick layers. For example, nucleation and stress management layers may be used.

A typical prior art III-N layer structure for III-N layers grown on silicon, shown in FIG. 1, includes a silicon substrate 10, a III-N buffer layer 11 atop the substrate, and an additional III-N layer 12 atop the buffer layer. Buffer layer 11 is a single composition III-N material that typically has a higher energy bandgap than that of the additional III-N layer 12. Therefore there can be an abrupt composition variation between the buffer layer 1 and the additional III-N layer 12. For example, buffer layer 11 can be AlN and the additional III-N layer 12 can be GaN. Careful control of the growth or deposition conditions and thickness of buffer layer 1 is commonly required to minimize the deleterious effects of the lattice and thermal mismatches between the additional III-N layer 12 and silicon substrate 10. These deleterious effects may include defect formation and stress in the layers. In the layer structure of FIG. 1, the additional III-N layer 12 is either under tension or is not in a sufficiently compressive strain state during growth to compensate for the tensile stress that occurs as the layers are being cooled to room temperature. Therefore during cool down, the net tensile stress can cause cracking of the layer.

For the prior art layer structure of FIG. 1, when the foreign substrate 10 is silicon, buffer layer 11 is AlN, and the additional III-N layer 12 is AlₓGa₁₋ₓN or GaN, the additional III-N layer 12 may be under compressive stress at growth temperature if it is sufficiently thin, but will be under less compressive stress or under tensile stress at growth temperature if it is grown thicker. Hence, a sufficiently thick additional III-N layer, which may be necessary for many device applications, may not be possible with this prior art layer structure.

Another prior art layer structure shown in FIG. 2 includes a graded III-N buffer layer 13 grown atop silicon substrate 10, rather than the single composition buffer layer shown in FIG. 1. The structure in FIG. 2 includes an additional III-N layer 12, such as GaN, grown atop the graded buffer layer 13. Layer 13, which may be AlₓGa₁₋ₓN with x≦1, includes a continuous grade in composition (i.e., x varies continuously throughout the layer). The composition of buffer layer 13 is graded such that the energy bandgap is greatest at the interface with silicon substrate 10, and decreases to a minimum at the interface with the additional III-N layer 12. The implementation of the graded III-N buffer layer shown in FIG. 2 can result in the subsequently grown additional III-N layer 12 being under more compressive stress during growth than the additional III-N layer 12 grown atop the single composition buffer layer shown in FIG. 1. The effects of the tensile stress of the layer structure as it is cooled to room temperature, such as cracking or defect formation, are mitigated by use of a graded buffer layer. However, for the layer structure of FIG. 2, it has been shown that the maximum thickness of the additional III-N layer 12 that can be grown without the formation of substantial dislocations and other defects may be limited.

In many applications in which III-N heteroepitaxial layers are used, it may be necessary that substantially thick III-N epitaxial layers of adequate quality be grown on the foreign substrates. However, with these prior art layer structures, the maximum thickness of the additional epitaxial III-N layer 12 in FIGS. 1 and 2, that can be grown without sustaining substantial defects may be limited. If these III-N epitaxial layers are grown too thick, tensile stress in the layer becomes substantial, which can cause cracking upon cooling.

### SUMMARY OF THE DISCLOSURE

In one aspect, a III-N layer structure is described that includes a III-N buffer layer on a foreign substrate, an additional III-N layer, a first III-N structure, and a second III-N layer structure. The first III-N structure atop the III-N buffer layer includes at least two III-N layers, each having an aluminum composition, and the III-N layer of the two III-N layers that is closer to the III-N buffer layer having the larger aluminum composition. The second III-N structure includes a III-N superlattice, the III-N superlattice including at least two III-N well layers interleaved with at least two III-N barrier layers, the barrier layers each having an aluminum composition. The first III-N structure and the second III-N structure are between the additional III-N layer and the foreign substrate.

For layer structures described above, one or more of the following may be applicable. The difference between the aluminum compositions of the at least two III-N well layers and the aluminum compositions of the at least two III-N barrier layers can be less than about 0.5 or less than about 0.2. The thickness of each of the III-N well layers can be between about 20 and 150 nm. The thickness of each of the III-N barrier layers can be less than about 100 Å or less than about 20 Å. The III-N barrier layers can have different thicknesses. The III-N barrier layers can have aluminum compositions between about 1 and 50 percent or between about 1 and 20 percent. The barrier layers can be AlGaN and the well layers can be GaN. The III-N well or barrier layers can be doped with a dopant selected from the group consisting of Fe, Mg, and B. The foreign substrate can be silicon. The foreign substrate can be selected from the group consisting of SiC, sapphire, and zinc oxide. The foreign substrate and the III-N layers each have thermal expansion coefficients, and the thermal expansion coefficient of the foreign substrate is can be smaller than the thermal expansion coefficient of one of the III-N layers. The second III-N structure can be atop the first III-N structure. The III-N buffer layer can be AlN. The additional III-N layer can be GaN or AlGaN. The additional III-N layer can be at least 2 microns thick or at least 5 microns thick. The additional III-N layer can be an epitaxial layer. Further layers atop the additional III-N layer can be included in the structure.

In another aspect, a III-N layer structure is described that includes a III-N buffer layer on a foreign substrate, an additional III-N layer, a first III-N structure, and a second III-N structure. The first III-N structure includes at least two AlₓGa_{y}N layers where x+y is less than or equal to 1, and the layer of the two layers that is closer to the III-N buffer layer can have the larger aluminum composition. The second III-N structure includes a III-N superlattice, the III-N superlattice including at least two III-N well layers interleaved with at least two III-N barrier layers, the barrier layers each having an aluminum composition. The first III-N structure and the second III-N structure can be between the additional III-N layer and the foreign substrate. For the layer structures described above, one or more of the following may be applicable. Each of the AlₓGa_{y}N layers can further include an element selected from the group consisting of Indium, Boron, Phosphorus, Arsenic, and Antimony. The difference between the aluminum compositions of the at least two III-N well layers and the aluminum compositions of the at least two III-N barrier layers can be less than about 0.5 or less than about 0.2. The thickness of each of the III-N well layers can be between about 20 and 150 nm. The thickness of each of the III-N barrier layers can be less than about 100 Å or less than about 20 Å. The III-N barrier layers can have different thicknesses. The III-N barrier layers can have aluminum compositions between about 1 and 50 percent or between about 1 and 20 percent. The III-N well or barrier layers can be doped with a dopant selected from the group consisting of Fe, Mg, and B. The barrier layers can be AlGaN and the well layers can be GaN.

The foreign substrate can be silicon or can be selected from the group consisting of SiC, sapphire, and zinc oxide. The foreign substrate and the AlₓGa_{y}N layers each can have thermal expansion coefficients, and the thermal expansion coefficient of the foreign substrate can be smaller than the thermal expansion coefficient of one of the III-N layers. The second III-N structure can be atop the first III-N structure. The III-N buffer layer can be AlN. The additional layer can be GaN or AlGaN. The additional III-N layer can be at least 2 microns thick or at least 5 microns thick, and can be an epitaxial layer. Further layers atop the additional layer can be included in the structure. The difference in compositions between adjacent III-N layers in III-N layer structures typically needs to be small to minimize the effects of the thermal and lattice mismatches between adjacently grown III-N layers, and also to substantially reduce or eliminate mobile charge in the structure. The layer structures described may allow for sufficiently thick III-N material layers on foreign substrates without inducing undesirable mobile charge in the III-N layers.

### DESCRIPTION OF DRAWINGS

FIGS. 1-2 are schematic cross-sectional views of prior art III-N layer structures on foreign substrates.

FIG. 3 is a schematic cross-sectional view of a III-N layer structure on a foreign substrate of an embodiment of the invention.

FIG. 4 is a schematic cross-sectional view of a portion of a III-N layer structure of an embodiment of the invention.

FIG. 5 is a schematic cross-sectional view of a superlattice structure of an embodiment of the invention.

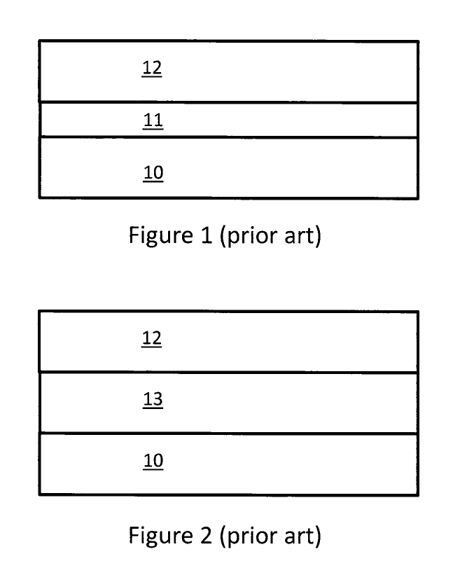

### DETAILED DESCRIPTION

Devices formed by layer structures that include or are formed of III-N semiconductor layers, such as GaN and its alloys, grown atop foreign substrates, (i.e., substrates that differ substantially in composition and/or lattice structure from that of the deposited layers), such as silicon (Si), silicon carbide (SiC), or sapphire (Al₂O₃), are described herein. As used herein, the terms III-Nitride or III-N materials, layers or devices refer to a material or device comprised of a compound semiconductor material according to the stoichiometric formula AlₓIn_{y}Ga_{z}N, where x+y+z is about 1. Here, x, y, and z are compositions of Al, In and Ga, respectively.

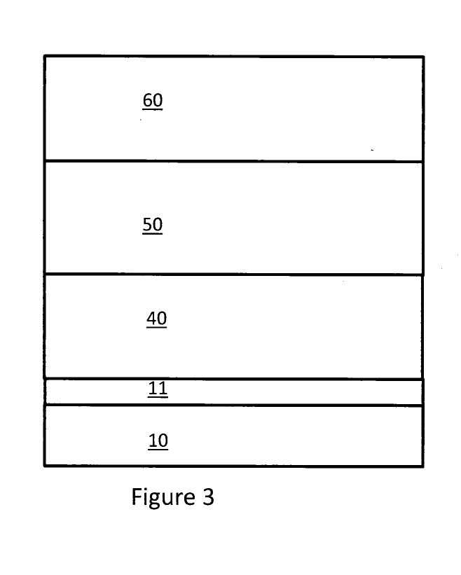

FIG. 3 shows a layer structure formed of layers of III-Nitride semiconductor materials on a foreign substrate 10, such as silicon. The layer structure includes silicon substrate 10, a III-N buffer layer 11, such as AlN, atop substrate 10, a first III-N structure 40 atop buffer layer 11, a second III-N structure 50 atop the first III-N structure 40, and an additional III-N layer 60, such as GaN or AlGaN, atop the second III-N structure 50. The first III-N structure 40, which is described in detail below, includes at least two AlₓGa_{y}N layers, where x+y is about 1, or less than or equal to 1, and each of the layers may further include other elements such as Indium (In), Boron (B), Phosphorus (P), Arsenic (As), or Antimony, (Sb).

Each layer of the first III-N structure 40 can have a substantially uniform Al composition within the layer, the layer closest to the substrate 10 having the largest Al composition, and each subsequent layer having an Al composition which is smaller than that of the layer directly beneath it, such that the layer farthest from the substrate has the smallest Al composition.

The second III-N structure 50, also described in detail below, is a III-N superlattice, or a III-N superlattice with a modulated composition. As used herein, a superlattice is a series of semiconductor layers stacked in a single direction for which, with the possible exception of the outermost layers, each intermediate layer directly contacts two other superlattice layers, both of which have either a larger or a smaller energy bandgap than that of the intermediate layer directly contacting it. The two superlattice layers are on opposite sides of the intermediate layer. The layers with energy bandgaps larger than those of the adjacent superlattice layers are referred to as barrier layers. The layers with energy bandgaps smaller than those of adjacent superlattice layers are referred to as well layers. As used herein, a superlattice with modulated composition is a superlattice in which the compositional makeup of different barrier layers or different well layers varies. For example, a GaN/AlGaN superlattice with modulated composition is a superlattice with AlGaN barrier layers that vary in aluminum composition from one barrier layer to the other. A GaN/AlGaN superlattice with modulated composition can include the following sequence of layers: GaN, AlₓGa₁₋ₓN, GaN, Al_{y}Ga_{1-y}N, GaN, Al_{z}Ga_{1-z}N, where x, y, and z are not all equal. The well layers are GaN and the barrier layers are AlGaN with dissimilar aluminum compositions. A superlattice of modulated composition, in addition to having a variation in composition of the layers, can also have a variation in layer thicknesses, such that the thickness of well and barrier layers can change from one layer to another. The second III-N structure 50 includes periodically alternating layers of III-N well layers and barrier layers, and can include at least two sets of III-N well and barrier layers, but typically may include more.

The inclusion of the first III-N structure 40 in the III-N multilayer structure of FIG. 3 can result in less stress and/or strain in the III-N layers 50 and 60 that overlie it than would have been the case had the first III-N structure 40 been omitted. In general, all III-N layers grown on silicon substrates, as well as other foreign substrates that have smaller thermal expansion coefficients than the III-N layers, need to be under sufficiently large compressive stress during growth so that during or after the time that the layers are cooled from growth temperature to room temperature (the time when the stress in the layers becomes more tensile and/or less compressive), defects associated with strain relief are not formed in the III-N layers. Hence, with the presence of the first III-N structure 40, it may be possible to grow substantially thicker III-N layers above it. For example, the additional III-N layer 60 may be grown substantially thicker, such as thicker than about 2 microns, thicker than about 3 microns, thicker than about 5 microns, or thicker than about 10 microns without the second III-N structure 50 needing to provide as much stress control as would have been necessary had the first III-N structure 40 been omitted.

Consequently, the III-N layer structure of FIG. 3 is characterized in that the difference in compositions between adjacent III-N well and barrier layers within the second III-N structure 50 can be small. For example, each III-N barrier layer within the second III-N structure 50 can have an Al composition that differs by about 0.5 or less, about 0.2 or less, about 0.1 or less, or about 0.05 or less, from that of each of the III-N well layers.

Abrupt changes in Al composition between adjacent III-N well and barrier layers in the second III-N structure 50 can induce undesirable excess electrons or two-dimensional electron gasses (2DEGs) in the III-N well layers if there is too high of an Al compositional difference between the two layers. Layer structures with small compositional differences between adjacent III-N layers, as in the III-N layer structure of FIG. 3, can substantially eliminate mobile charge in the structure, which can be advantageous for III-N device performance. In many devices that require III-N layers grown on foreign substrates, for example III-N high electron mobility transistors (HEMTs), the devices also require a conducting channel, such as a two-dimensional electron gas (2DEG), in the channel and contact regions of the III-N material layers. However, there must be no substantial amount of mobile charge in other portions of the III-N material layers, such as the portions between the device channel and the substrate. For example, in III-N HEMTs, the presence of mobile charge in the regions of III-N material between the channel and the substrate can lead to degradation of performance at higher frequencies, as well as leakage currents and reduced breakdown voltages.

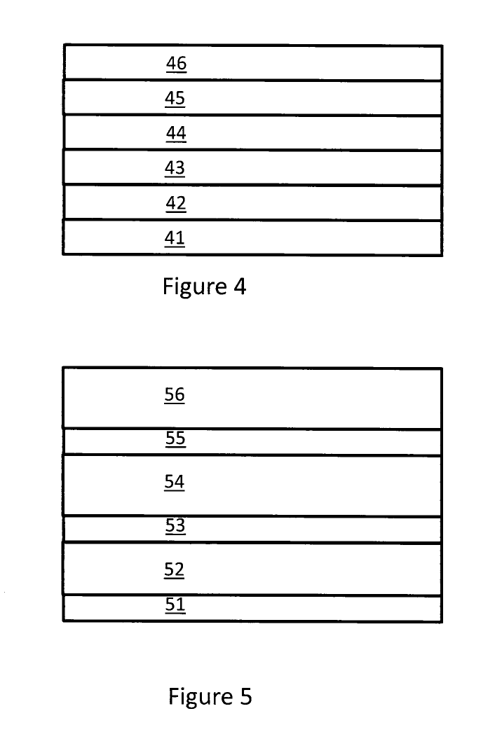

The first III-N structure 40, an example of which is illustrated schematically in FIG. 4, includes a plurality of III-N layers 41-46 of decreasing aluminum composition, so that the aluminum composition is reduced in steps. For example, layers 41-46 can be AlₓGa_{y}Z_{1-x-y}N layers, where x+y is about 1 or less than or equal to 1, and Z is another element such as In or B, or a combination of other elements. In some implementations, layers 41-46 are AlₓGa_{y}N, where x+y is about 1. Each of III-N layers 41-46 has a distinct aluminum composition x that is less that the aluminum composition of the underlying III-N layer. The difference in aluminum composition of successive layers in the first III-N structure 40 shown in FIG. 4 can be small, for example less than or equal to about 0.2, 0.1, or 0.05. That is, each layer in the first III-N structure 40 can have an aluminum composition that differs by about 0.2 or less, about 0.1 or less, or about 0.05 or less from at least one other layer in the first III-N structure 40. III-N layer 41 is the layer in the first III-N structure 40 closest to buffer layer 11 (shown in FIG. 3). III-N layer 41 has the highest aluminum composition, x, of the III-N layers 41-46 in the first III-N structure 40.

For example, III-N layer 41 can be AlₓGa₁₋ₓN and have an aluminum composition x of about 0.6. III-N layer 42, atop III-N layer 41, can be AlₐGa₁₋ₐN and have an aluminum composition, a, which is less than that of III-N layer 41, such as about 0.5. Likewise, each subsequent III-N layer, which in FIG. 4 includes III-N layers 43, 44, 45, and 46, has an Al composition less than that of its underlying III-N layer. III-N layer 46 is the layer in the first III-N structure 40 furthest from buffer layer 11 (FIG. 3). III-N layer 46 has the lowest aluminum composition of the III-N layers in the first III-N structure 40. For example, III-N layer 46 can be Al_{b}Ga_{1-b}N and have an aluminum composition b of about 0.2. The first III-N structure 40 can include layers with aluminum compositions in the range of about 0.9 to 0.1, such as between about 0.6 and 0.2, and can include more or fewer III-N layers than those shown in the example in FIG. 4. In some implementations, the first III-N structure 40 includes at least two III-N or AlₓGa₁₋ₓN layers.

FIG. 5 shows an example of the layer structure of the second III-N structure 50 of FIG. 3. The second III-N structure 50 includes a III-N superlattice or superlattice with modulated composition, including periodically alternating layers of III-N well layers 52, 54, and 56, which can for example be GaN, and III-N barrier layers 51, 53, and 55, which for example can be AlGaN or AlInGaN. The thickness of each of the III-N well layers 52, 54, and 56 can be between about 20 and 150 nm. Each III-N well layer in the second III-N structure 50 can have a dissimilar thickness to that of other III-N well layers. For example, the thickness of each subsequent III-N well layer, from bottom to top, may be greater than that of the previous III-N well layer. The thickness of each of the III-N barrier layers 51, 53, and 55 can be about 100 Å or less, about 80 Å or less, or about 50 Å or less, and may be more than about 20 Å. Each III-N barrier layer in the second III-N structure 50 can have dissimilar thickness to that of the other III-N barrier layers.

III-N barrier layers 51, 53, and 55 can have low aluminum composition, such as between about 1 and 50 percent, between about 2 and 20 percent, or between about 2 and 10 percent. Each III-N barrier layer in the second III-N structure 50 can have dissimilar aluminum composition to that of other III-N barrier layers, and all III-N barrier layers 51, 53, and 55 can have aluminum composition less than or equal to about 0.5, 0.2, or 0.1. For example, III-N barrier layer 51 can be AlₓGa₁₋ₓN with aluminum composition x of about 0.1. III-N barrier layer 53 can be Al_{y}Ga_{1-y}N with aluminum composition y of about 0.05. III-N barrier layer 55 can be Al_{z}Ga_{1-z}N with aluminum composition z of about 0.01. The second III-N layer structure 50 can include additional or fewer well/barrier layers than those shown in the example of FIG. 5. In some implementations, at least two well layers and at least two barrier layers are included.

In some implementations, at least one of the well and/or barrier layers in the second III-N structure 50 is doped, such as with Fe, Mg, or B, in order to compensate or eliminate any mobile charge that may have been induced in these layers. Inclusion of these dopants (particularly in large concentrations) in III-N devices such as transistors or HEMTs has been known to cause adverse effects, such as DC-to-RF dispersion.

However, because of the relatively small differences in composition between the well and barrier layers in the second III-N structure 50, the compensating dopant concentration can be made small while still substantially eliminating or compensating the mobile charge in the structure. For example, the compensating dopant concentration can be made smaller than in a similar layer structure that supports approximately the same amount of strain energy in III-N epitaxial layer 60, but does not include a first III-N structure 40, since a layer structure without a first III-N structure 40 would require larger compositional differences between adjacent well and barrier layers in the superlattice structure.

Other possible additions or modifications to the layer structure of FIG. 3 can include the following. Substrate 10 can be SiC, sapphire, zinc oxide, or any foreign substrate for III-N materials for which the thermal expansion coefficient of the substrate is smaller than that of at least one of the III-N layers. The order of the first III-N structure 40 and the second III-N structure 50 can be switched. That is, the second III-N structure 50 can be between the first III-N structure 40 and the III-N buffer layer 11. III-N superlattices or III-N superlattices with modulated compositions can be included between layers of the first III-N structure 40, either in addition to or in place of the second III-N structure 50. The additional III-N layer 60 can be at least about 2 microns thick, at least about 4 microns thick, at least about 6 microns thick, or at least about 8 microns thick. Additional III-N layers can be included atop III-N layer 60. The III-N materials can be substantially free of cracks. The III-N materials can be III-polar (oriented in the [0 0 0 1] direction), N-polar (oriented in the [0 0 0 1 bar] direction), or semi-polar III-N materials. A III-N semiconductor device, such as a III-N transistor, diode, laser, or LED, can be formed on the layer structure of FIG. 3. These additional features can be used individually or in combination with one another.

A number of implementations have been described. Nevertheless, it will be understood that various modifications may be made without departing from the spirit and scope of the techniques and structures described herein. Accordingly, other implementations are within the scope of the following claims.

What is claimed is:

1. A III-N layer structure, comprising:
a III-N buffer layer on a foreign substrate;
an additional III-N layer;
a first III-N structure atop the III-N buffer layer comprising at least two III-N layers, each having an aluminum composition, and the III-N layer of the two III-N layers that is closer to the III-N buffer layer having a larger aluminum composition; and
a second III-N structure comprising a III-N superlattice, the III-N superlattice comprising at least two III-N well layers interleaved with at least two III-N barrier layers, the well layers and the barrier layers each having an aluminum composition, wherein the first III-N structure and the second III-N structure are between the additional III-N layer and the foreign substrate.

2. The III-N layer structure of claim 1, wherein a difference between the aluminum compositions of the at least two III-N well layers and the aluminum compositions of the at least two III-N barrier layers is less than about 0.5.

3. The III-N layer structure of claim 1, wherein a difference between the aluminum compositions of the at least two III-N well layers and the aluminum compositions of the at least two III-N barrier layers is less than about 0.2.

4. The III-N layer structure of claim 1, wherein the thickness of each of the III-N well layers is between about 20 and 150 nm.

5. The III-N layer structure of claim 1, wherein the thickness of each of the III-N barrier layers is less than about 100 Å.

6. The III-N layer structure of claim 1, wherein the thickness of each of the III-N barrier layers is less than about 20 Å.

7. The III-N layer structure of claim 1, wherein the III-N barrier layers have different thicknesses.

8. The III-N layer structure of claim 1, wherein the III-N barrier layers have aluminum compositions between about 1 and 50 percent.

9. The III-N layer structure of claim 1, wherein the III-N barrier layers have aluminum compositions between about 1 and 20 percent.

10. The III-N layer structure of claim 1, wherein the barrier layers are AlGaN and the well layers are GaN.

11. The III-N layer structure of claim 1, wherein the III-N well or barrier layers are doped with a dopant selected from the class consisting of Fe, Mg, and B.

12. The III-N layer structure of claim 1, wherein the foreign substrate is silicon.

13. The III-N layer structure of claim 1, wherein the foreign substrate is selected from the group consisting of SiC, sapphire and zinc oxide.

14. The III-N layer structure of claim 1, wherein the foreign substrate and the III-N layers each have thermal expansion coefficients, and wherein the thermal expansion coefficient of the foreign substrate is smaller than the thermal expansion coefficient of one of the III-N layers.

15. The III-N layer structure of claim 1, wherein the second III-N structure is atop the first III-N structure.

16. The III-N layer structure of claim 1, wherein the III-N buffer layer is AlN.

17. The III-N layer structure of claim 1, wherein the additional III-N layer is GaN.

18. The III-N layer structure of claim 1, wherein the additional III-N layer is AlGaN.

19. The III-N layer structure of claim 1, wherein the additional III-N layer is at least 2 microns thick.

20. The III-N layer structure of claim 1, wherein the additional III-N layer is at least 5 microns thick.

21. The III-N layer structure of claim 1, wherein the additional III-N layer is an epitaxial layer.

22. The III-N layer structure of claim 1, having further layers atop the additional III-N layer.

23. A III-N layer structure, comprising:
a III-N buffer layer on a foreign substrate;
an additional III-N layer;
a first III-N structure comprising at least two AlₓGa_{y}N layers where x+y is less than or equal to 1, and a layer of the two layers that is closer to the III-N buffer layer having a larger aluminum composition; and
a second III-N structure comprising a III-N superlattice, the III-N superlattice comprising at least two III-N well layers interleaved with at least two III-N barrier layers, the well layers and the barrier layers each having an aluminum composition, wherein the first III-N structure and the second III-N structure are between the additional III-N layer and the foreign substrate.

24. The III-N layer structure of claim 23, wherein each of the AlₓGa_{y}N layers further includes an element selected from the group consisting of Indium, Boron, Phosphorus, Arsenic, and Antimony.

25. The III-N layer structure of claim 23, wherein a difference between the aluminum compositions of the at least two III-N well layers and the aluminum compositions of the at least two III-N barrier layers is less than about 0.5.

26. The III-N layer structure of claim 23, wherein a difference between the aluminum compositions of the at least two III-N well layers and the aluminum compositions of the at least two III-N barrier layers is less than about 0.2.

27. The III-N layer structure of claim 23, wherein the thickness of each of the III-N well layers is between about 20 and 150 nm.

28. The III-N layer structure of claim 23, wherein the thickness of each of the III-N barrier layers is less than about 100 Å.

29. The III-N layer structure of claim 23, wherein the thickness of each of the III-N barrier layers is less than about 20 Å.

30. The III-N layer structure of claim 23, wherein the III-N barrier layers have different thicknesses.

31. The III-N layer structure of claim 23, wherein the III-N barrier layers have aluminum compositions between about 1 and 50 percent.

32. The III-N layer structure of claim 23, wherein the III-N barrier layers have aluminum compositions between about 1 and 20 percent.

33. The III-N layer structure of claim 23, wherein the III-N well or barrier layers are doped with a dopant selected from the class consisting of Fe, Mg, and B.

34. The III-N layer structure of claim 23, wherein the barrier layers are AlGaN and the well layers are GaN.

35. The III-N layer structure of claim 23, wherein the foreign substrate is silicon.

36. The III-N layer structure of claim 23, wherein the foreign substrate is selected from the group consisting of SiC, sapphire and zinc oxide.

37. The III-N layer structure of claim 23, wherein the foreign substrate and the III-N layers each have thermal expansion coefficients, and wherein the thermal expansion coefficient of the foreign substrate is smaller than the thermal expansion coefficient of one of the III-N layers.

38. The III-N layer structure of claim 23, wherein the second III-N structure is atop the first III-N structure.

39. The III-N layer structure of claim 23, wherein the III-N buffer layer is AlN.

40. The III-N layer structure of claim 23, wherein the additional III-N layer is GaN.

41. The III-N layer structure of claim 23, wherein the additional III-N layer is AlGaN.

42. The III-N layer structure of claim 23, wherein the additional III-N layer is at least 2 microns thick.

43. The III-N layer structure of claim 23, wherein the additional III-N layer is at least 5 microns thick.

44. The III-N layer structure of claim 23, wherein the additional III-N layer is an epitaxial layer.

45. The III-N layer structure of claim 23, having further layers atop the additional III-N layer.
